(19) United States
(12) Patent Application Publication
(10) Pub. No.: US 2025/0380617 A1
(43) Pub. Date: Dec. 11, 2025

(54) CENTRAL ELECTRODE STRUCTURE

(71) Applicant: International Business Machines Corporation, Armonk, NY (US)

(72) Inventor: Oscar van der Straten, Guilderland Center, NY (US)

(21) Appl. No.: 18/736,010

(22) Filed: Jun. 6, 2024

(51) Int. Cl. H10N 50/80; H10B 61/00; H10N 50/01; H10N 50/10

(52) U.S. Cl. CPC H10N 50/80; H10B 61/00; H10N 50/01; H10N 50/10

(57) ABSTRACT

A memory device is provided that includes a central electrode structure that extends entirely through, and is laterally surrounded by, a hollow MTJ-containing pillar. The central electrode structure includes spaced apart top and bottom electrodes. In the memory device, the hollow MTJ-containing pillar is contacted by the bottom electrode from below and by the top electrode from above.

### BACKGROUND

The present application relates to a memory device, and more particularly to a memory device including a central electrode structure that extends through a solid magnetic tunnel junction (MTJ)-containing pillar.

Magnetoresistive random access memory (MRAM), is a non-volatile random access memory technology in which data is stored by magnetic storage elements. These elements are typically formed from two ferromagnetic plates, each of which can hold a magnetization, separated by a thin dielectric layer (i.e., a tunnel barrier). One of the two plates is a permanent magnetic set to a particular polarity (i.e., a magnetic reference layer); the other plate's magnetization can be changed to match that of an external field to store memory (i.e., a magnetic free layer). Such a configuration is known as a magnetic tunnel junction (MTJ)-containing pillar. In leading-edge or neuromorphic computing systems, an MTJ-containing pillar is typically embedded within a back-end-of-the-line (BEOL) structure.

### SUMMARY

A memory device is provided that includes a central electrode structure that extends entirely through, and is laterally surrounded by, a hollow MTJ-containing pillar. The central electrode structure includes spaced apart top and bottom electrodes. In the memory device, the hollow MTJ-containing pillar is contacted by the bottom electrode from below and by the top electrode from above. The memory device including the central electrode structure is devoid of re-sputtered bottom electrode metal particles and has a reduced circular edge roughness.

In one embodiment of the present application, the memory device includes a first electrically conductive structure, a metal cap located on the first electrically conductive structure, and a central electrode structure that extends entirely through, and is laterally surrounded by, a hollow MTJ-containing pillar. In this embodiment, the central electrode structure includes a top electrode spaced apart from a bottom electrode in which the bottom electrode is in direct physical contact with the metal cap. The memory device further includes a second electrically conductive structure located above, and in electrical contact with, the top electrode.

In another embodiment of the present application, the memory device includes a first electrically conductive structure, a metal cap located on the first electrically conductive structure, and a central electrode structure that extends entirely through, and is laterally surrounded by, a hollow MTJ-containing pillar. In this embodiment, the central electrode structure includes a top electrode spaced apart from a bottom electrode, a bottom electrode liner located on a sidewall and a bottom surface of the bottom electrode, and a top electrode liner located on a sidewall and a bottom surface of the top electrode. In this embodiment, the bottom electrode liner lands on the metal cap. The memory device further includes a second electrically conductive structure located above, and in electrical contact with, the top electrode.

In a further embodiment of the present application, the memory device includes a first electrically conductive structure, a metal cap located on the first electrically conductive structure, and a central electrode structure that extends entirely through, and is laterally surrounded by, a hollow MTJ-containing pillar. In this embodiment, the central electrode structure includes a top electrode spaced apart from a bottom electrode and an electrode liner located on a sidewall and a bottom surface of either the top electrode or the bottom electrode. Also in this embodiment, the bottom electrode is in electrical contact (either directly or indirectly) with the metal cap. The memory device further includes a second electrically conductive structure located above, and in electrical contact with, the top electrode.

### BRIEF DESCRIPTION OF THE DRAWINGS

FIG. 1 is a cross sectional view of an exemplary structure that can be employed in the present application, the exemplary structure including a first electrically conductive structure embedded in a first interlayer dielectric (ILD) layer, and a dielectric cap located on the first ILD layer and the first electrically conductive structure.

FIG. 2 is a cross sectional view of the exemplary structure of FIG. 1 after patterning the dielectric cap to physically expose the first electrically conductive structure.

FIG. 3 is a cross sectional view of the exemplary structure of FIG. 2 after forming a metal cap on the physically exposed first electrically conductive structure and adjacent to the patterned dielectric cap.

FIG. 4 is a cross sectional view of the exemplary structure of FIG. 3 after forming a second ILD layer on the patterned dielectric cap and the metal cap.

FIG. 5 is a cross sectional view of the exemplary structure of FIG. 4 after forming a MTJ-containing stack including a blanket bottom magnetic material containing layer, a blanket tunnel barrier layer and a blanket upper magnetic material containing layer.

FIG. 6 is a cross sectional view of the exemplary structure of FIG. 5 after forming a patterned dielectric hard mask on the MTJ-containing stack.

FIG. 7 is a cross sectional view of the exemplary structure of FIG. 6 after patterning the MTJ-containing stack including the blanket bottom magnetic material containing layer, the blanket tunnel barrier layer and the blank upper magnetic material containing layer to provide a solid MTJ-containing pillar including a bottom magnetic material containing layer, a tunnel barrier layer and an upper magnetic material containing layer.

FIG. 8 is a cross sectional view of the exemplary structure of FIG. 7 after removing the patterned dielectric hard mask from on top of the solid MTJ-containing pillar.

FIG. 9 is a cross sectional view of the exemplary structure of FIG. 8 after forming an encapsulation liner on a sidewall of the solid MTJ-containing pillar.

FIG. 10 is a cross sectional view of the exemplary structure of FIG. 9 after forming a third ILD layer adjacent to the encapsulation liner and on the second ILD layer.

FIG. 11 is a cross sectional view of the exemplary structure of FIG. 10 after forming an opening through the third ILD layer, the solid MTJ-containing pillar and the second ILD layer to physically expose a portion of the metal cap, the opening is laterally surrounded by a remaining portion of the solid MTJ-containing pillar (this remaining portion of the solid MTJ-containing pillar is referred to herein as a hollow MTJ-containing pillar).

FIG. 12 is a cross sectional view of the exemplary structure of FIG. 11 after filling the opening with a bottom electrode material containing layer.

FIG. 13 is a cross sectional view of the exemplary structure of FIG. 12 after recessing the bottom electrode material containing layer to a height that is located between a topmost surface and a bottom surface of the bottom magnetic material containing layer of the hollow MTJ-containing pillar.

FIG. 14 is a cross sectional view of the exemplary structure of FIG. 13 after forming an electrode separating dielectric material layer on the recessed bottom electrode layer (i.e., bottom electrode).

FIG. 15 is a cross sectional view of the exemplary structure of FIG. 14 after forming a top electrode on the electrode separating dielectric material layer.

FIG. 16 is a cross sectional view of the exemplary structure of FIG. 15 after forming a fourth ILD layer.

FIG. 17 is a cross sectional view of the exemplary structure of FIG. 16 after forming a second electrically conductive structure embedded in the fourth ILD layer and in electrical contact with the top electrode.

FIG. 18 is a cross sectional view of the exemplary structure of FIG. 11 after filling the opening with a metal liner and a bottom electrode material containing layer.

FIG. 19 is a cross sectional view of the exemplary structure of FIG. 18 after recessing the metal liner and the bottom electrode material containing layer to a height that is located between a topmost surface and a bottom surface of the bottom magnetic material containing layer of the hollow MTJ-containing pillar.

FIG. 20 is a cross sectional view of the exemplary structure of FIG. 19 after forming an electrode separating dielectric material layer on the recessed bottom electrode layer (i.e., bottom electrode).

FIG. 21 is a cross sectional view of the exemplary structure of FIG. 20 after forming a top electrode on the electrode separating dielectric material layer.

FIG. 22 is a cross sectional view of the exemplary structure of FIG. 21 after forming a fourth ILD layer.

FIG. 23 is a cross sectional view of the exemplary structure of FIG. 22 after forming a second electrically conductive structure embedded in the fourth ILD layer and in electrical contact with the top electrode.

FIG. 24 shows a top down view of a central electrode structure that is laterally surrounded by a hollow MTJ-containing pillar.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

For high performance MRAM devices based on perpendicular MTJ-containing pillars, well-defined interfaces and interface control are essential. Embedded MTJ-containing pillars are usually formed by patterning a blanket MTJ-containing stack utilizing one of reactive ion etching (RIE) or ion beam etching (IBE). Processing the blanket MTJ-containing stack into a MTJ-containing pillar utilizing RIE and IBE presents a major challenge, as it leads to shorts due to re-sputtering of the bottom electrode metal particles onto the sidewall of the MTJ-containing pillar. Another problem that arises with processing the blanket MTJ-containing stack is that a polycrystalline metal hard mask is used during the patterning of the blanket MTJ-containing stack. Grain boundaries and/or defects in the polycrystalline metal hard mask can be transferred into the MTJ-containing pillar during patterning of the blanket MTJ-containing stack resulting in MTJ-containing pillars with high circular edge roughness (CER) which can negatively impact memory device performance.

The present application circumvents the above re-sputtering and CER problems by forming a central electrode structure entirely through a solid MTJ-containing pillar such that the central electrode structure is laterally surrounded by a hollow MTJ-containing pillar. See, for example, FIG. 24. The hollow MTJ-containing pillar is derived from the solid MTJ-containing pillar during the formation of the central electrode structure. The central electrode structure includes spaced apart top and bottom electrodes. The hollow MTJ-containing pillar is contacted by the bottom electrode from below and by the top electrode from above. In the present application, both the solid and hollow MTJ-containing pillars are substantially circular. These and other aspects of the present application will now be described in greater detail.

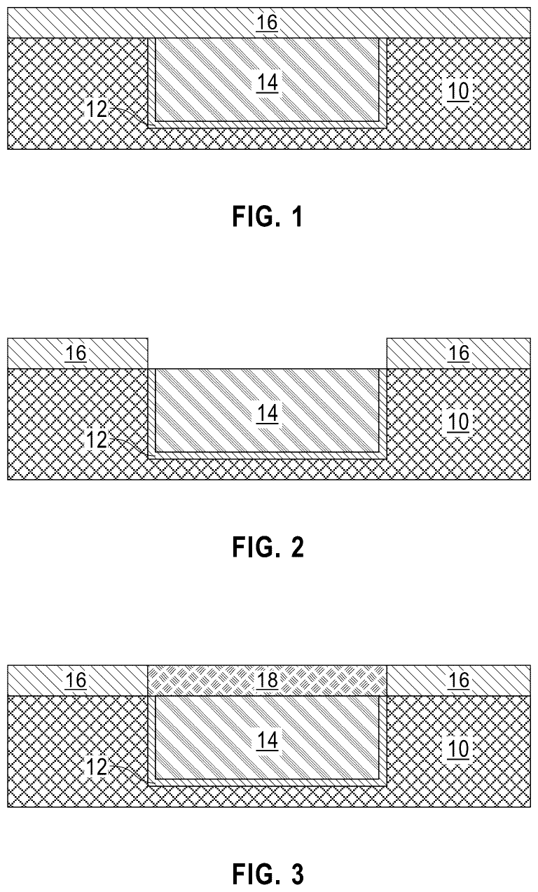

Referring first to FIG. 1, there is illustrated an exemplary structure that can be employed in the present application, the exemplary structure including a first electrically conductive structure 14 embedded in a first ILD layer 10, and a dielectric cap 16 located on the first ILD layer 10 and the first electrically conductive structure 14. In some embodiments and as is illustrated in FIG. 1, a first diffusion barrier liner 12 can be present along a sidewall and a surface of the first electrically conductive structure 14. In other embodiments, the first diffusion barrier liner 12 can be omitted. Collectively, the first electrically conductive structure 14, the optional first diffusion barrier liner 12 and the first ILD layer 10 provide a metal (or interconnect) level, Mn, wherein n is any integer starting from 1; the upper limit of ‘n’ can vary and can be predetermined by the manufacturer of a specific integrated circuit. Although FIG. 1 describes and illustrates a single first electrically conductive structure 14 embedded in the first ILD layer 10, the present application contemplates embodiments when more than one first electrically conductive structure 14 is embedded in the first ILD layer 10. When more than one first electrically conductive structure 14 is embedded in the first ILD layer 10, some or all of the first electrically conductive structures can be processed to include a central electrode structure that passes through a hollow MTJ-containing pillar in accordance with the present application.

In some embodiments, the first electrically conductive structure 14 can extend entirely through the first ILD layer 10. In other embodiments, the first electrically conductive structure 14 extends partially through the first ILD layer 10 and in such embodiments, the first electrically conductive structure 14 can be connected to another electrically conductive structure such as, for example, a metal line and/or a metal via.

Although not illustrated in any of the drawings of the present application, a substrate can be located beneath metal level, Mn. The substrate can include a front-end-of-the-line (FEOL) level including one or more semiconductor devices, such as, for example, field effect transistors located on a semiconductor material; a middle-of-the-line (MOL) level including a plurality of metal contact structures embedded in a MOL dielectric material layer; at least one lower interconnect level that includes a plurality of lower interconnect structures embedded in a lower interconnect dielectric material layer; or any combination thereof. In one example, the substrate includes a FEOL level and a MOL level.

The metal level, Mn, can be formed utilizing techniques that are known to those skilled in the art. In one embodiment, a damascene process can be used in forming metal level, Mn. A damascene process can include forming at least one opening into the first ILD layer 10, filling the opening with an optional diffusion barrier layer, and an electrically conductive material and, if needed, performing a planarization process such as, for example, chemical mechanical polishing (CMP) to remove the optional diffusion barrier layer and the electrically conductive material from the topmost surface of the first ILD layer 10. The diffusion barrier layer that remains in the opening can be referred to herein as the first diffusion barrier liner 12, and the electrically conductive material that remains in the opening can be referred to herein as the first electrically conductive structure 14. In some embodiments, and as shown in FIG. 1, the first electrically conductive structure 14 has a topmost surface that is substantially coplanar with a topmost surface of the first ILD layer 10 as well as with a topmost surface of the first diffusion barrier liner 12, if the same is present.

The first ILD layer 10 can be composed of a dielectric material such as, for example, silicon dioxide, silicon nitride, undoped silicate glass (USG), fluorosilicate glass (FSG), borophosphosilicate glass (BPSG), a spin-on low-k dielectric material, a chemical vapor deposition (CVD) low-k dielectric material or any combination thereof. The term “low-k” as used throughout the present application denotes a dielectric material that has a dielectric constant of less than 4.0. All dielectric constants mentioned herein as measured in a vacuum unless otherwise noted. Illustrative low-k dielectric materials that can be used as the first ILD layer 10 include, but are not limited to, silsesquioxanes, C doped oxides (i.e., organosilicates) that includes atoms of Si, C, O and H, thermosetting polyarylene ethers, or multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Although not shown, the first ILD layer 10 can include a multilayered structure that includes at least two different dielectric materials stacked one atop the other. The first ILD layer 10 can be formed utilizing a deposition process including, for example, chemical vapor deposition (CVD), plasma enhanced chemical vapor deposition (PECVD), evaporation or spin-on coating.

The diffusion barrier layer (and thus the first diffusion barrier liner 12) that can optionally be employed in the present application includes a diffusion barrier material (i.e., a material that serves as a barrier to prevent a conductive material such as copper from diffusing there through). Examples of diffusion barrier materials that can be used in providing the diffusion barrier layer (and thus the first diffusion barrier liner 12) include, but are not limited to, Ta, TaN, Ti, TiN, Ru, RuN, RuTa, RuTaN, W, or WN; in some instances of the present application chemical symbols, as found in the Periodic Table of Elements, are used instead of the full names of the elements or compounds. In some embodiments, the diffusion barrier material can include a material stack of diffusion barrier materials. In one example, the diffusion barrier material can be composed of a stack of Ta/TaN. The diffusion barrier layer can be formed by a deposition process such as, for example, CVD, PECVD, or physical vapor deposition (PVD).

The electrically conductive material that provides the first electrically conductive structure 14 can include an electrically conductive metal and/or an electrically conductive metal alloy. Illustrative examples of electrically conductive metals include, but are not limited to, Cu, W, Al, Co, or Ru. An illustrative example of an electrically conductive metal alloy includes Cu—Al alloy. The electrically conductive material that provides first electrically conductive structure 14 can be formed by a deposition process such as, for example, CVD, PECVD, PVD, sputtering or electroplating. In some embodiments, a reflow anneal can follow the deposition of the electrically conductive material that provides first electrically conductive structure 14. The electrically conductive structure 14 can be a metal via, a metal liner or a combined metal line/metal via.

After forming the metal level, Mn, dielectric cap 16 is formed. Dielectric cap 16 is composed of a dielectric capping material which is compositionally different from the dielectric material that provides the first ILD layer 10. The dielectric capping material that provides the dielectric cap 16 can include, but is not limited to, silicon nitride (SiN), or a dielectric containing atoms of silicon, nitrogen and carbon (i.e., SiNC). The dielectric cap 16 can be formed by a deposition process including, but not limited to, atomic layer deposition (ALD), CVD, PECVD or PVD.

Referring now to FIG. 2, there is illustrated the exemplary structure of FIG. 1 after patterning the dielectric cap 16 to physically expose the first electrically conductive structure 14. The patterning of the dielectric cap 16 includes lithographic patterning. Lithographic patterning includes forming a photoresist material on a layer/multilayered stack that needs to be patterned, exposing the as deposited photoresist material to a desired pattern of irradiation, developing the photoresist material and transferring the pattern from the developed photoresist material into the layer/multilayered stack that needs to be patterned, the transferring of the pattern can include one or more etching processes. The one or more etching processes can include dry etching and/or wet etching. Dry etching can include reactive ion etching (RIE), plasma etching or ion beam etching. Wet etching can include the use of a chemical etchant that is selective in removing physically exposed portions of the layer/multilayered stack that needs to be patterned. The photoresist material is removed after the pattern transfer process utilizing a material removal process that is selective in removing the photoresist material. In the present application, the patterning of the dielectric cap 16 forms an opening in the dielectric cap 16 that physically exposes the first electrically conductive structure 14. In some embodiments and as shown in FIG. 2, the opening can also physically expose a topmost surface of the first diffusion barrier liner 12, if the first diffusion barrier liner 12 is present. In other embodiments (not shown), the opening formed in the dielectric cap does not physically expose the first diffusion barrier liner 12.

Referring now to FIG. 3, there is illustrated the exemplary structure of FIG. 2 after forming a metal cap 18 on the physically exposed first electrically conductive structure 14 and adjacent to the patterned dielectric cap 16. The metal cap 18 is composed of a metal that is inert as compared to the electrically conductive material present in the first electrically conductive structure 14. Illustrative examples of such inert metals include, but are not limited to, Ta, W or Ru. The metal cap 18 can be formed by a deposition process, followed by planarization including CMP. The deposition process used in forming the metal cap 18 can include, for example, CVD, PECVD, PVD, sputtering or electroplating. The metal cap 18 has a topmost surface that is substantially coplanar with a topmost surface of the patterned dielectric cap 16.

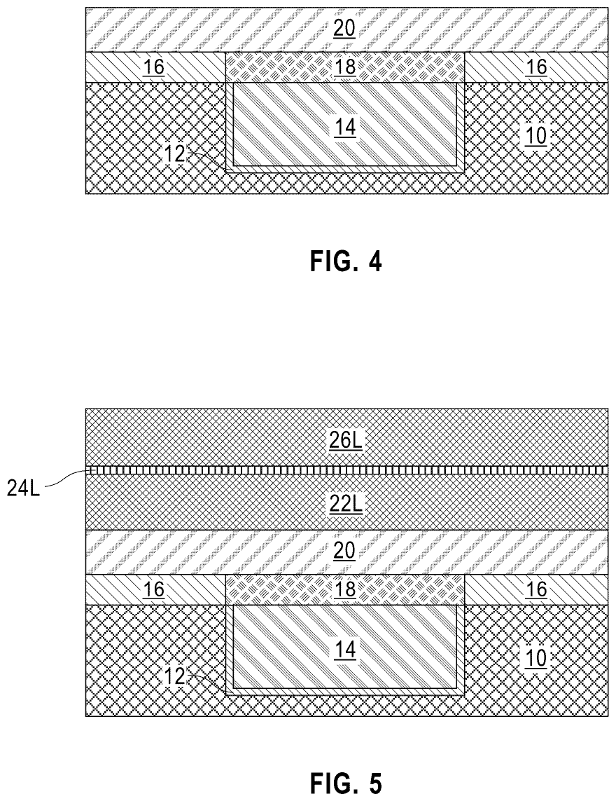

Referring now to FIG. 4, there is illustrated the exemplary structure of FIG. 3 after forming a second ILD layer 20 on the patterned dielectric cap 16 and the metal cap 18. The second ILD layer 20 can include a dielectric material as mentioned above for the first ILD layer 10. The dielectric material that provides the second ILD layer 20 can be compositionally the same as, or compositionally different from, the dielectric material that provides the first ILD layer 10. The dielectric material that provides the second ILD layer 20 is however compositionally different from the dielectric capping material that provides the dielectric cap 16. The dielectric cap 16 thus can be used as an etch stop layer during the subsequent formation of an opening that is formed into a solid MTJ-containing pillar that is subsequently formed on top of the second ILD layer 20. The second ILD layer 20 can be formed by a deposition process such as, for example, CVD, PECVD, evaporation or spin-on coating. A planarization process such as, for example, CMP, can follow the deposition of the dielectric material that provides the second ILD layer 20.

Referring now to FIG. 5, there is illustrated the exemplary structure of FIG. 4 after forming a MTJ-containing stack including a blanket bottom magnetic material containing layer 22L, a blanket tunnel barrier layer 24L and a blanket upper magnetic material containing layer 26L. The blanket bottom magnetic material containing layer 22L includes a magnetic pinned (or reference) material or a magnetic free material. The blanket upper magnetic material containing layer 26L includes the other of the magnetic pinned material or magnetic free material not employed in the blanket bottom magnetic material containing layer 22L. In one example, the blanket bottom magnetic material containing layer 22L includes a magnetic pinned (or reference) material, and the blanket upper magnetic material containing layer 26L includes a magnetic free material. In another example, the blanket bottom magnetic material containing layer 22L includes a magnetic free material, and the blanket upper magnetic material containing layer 26L includes a magnetic pinned (or reference) material.

In embodiments in which MTJ-containing stack includes a magnetic pinned (or reference) material as the blanket bottom magnetic material containing layer 22L and a magnetic free material as the blanket upper magnetic material containing layer 26L, the MTJ-containing stack (and the subsequently formed MTJ-containing pillar) can be referred to as a bottom pinned MTJ-containing stack (or bottom pinned MTJ-containing pillar). In embodiments in which MTJ-containing stack includes a magnetic free material as the blanket bottom magnetic material containing layer 22L and a magnetic pinned (or reference) material as the blanket upper magnetic material containing layer 26L, the MTJ-containing stack (and the subsequently formed MTJ-containing pillar) can be referred to as a top pinned MTJ-containing stack (or top pinned MTJ containing pillar).

In some embodiments, the bottom pinned MTJ-containing stack can also include an optional blanket layer of metal seed material (not shown). In the bottom pinned MTJ-containing material stack, the optional blanket layer of metal seed material is formed directly beneath the blanket bottom magnetic material containing layer 24L. In some embodiments, the top pinned MTJ-containing stack can also include an optional blanket layer of metal seed material (not shown). In the top pinned MTJ-containing material stack, the optional blanket layer of metal seed material is formed directly beneath the blanket upper magnetic material containing layer 26L.

In some embodiments, the MTJ-containing stack can also include a blanket layer of MTJ cap material (not shown) located on the blanket upper magnetic material containing layer 26L. In some embodiments, the magnetic free material can be composed of a single magnetic free material or a multilayered stack of magnetic free materials. In some embodiments, the magnetic free material includes a non-magnetic spacer material located between a first magnetic free material and a second magnetic free material.

The magnetic pinned material has a fixed magnetization. The magnetic pinned material can be composed of a metal or metal alloy (or a stack thereof) that includes one or more metals exhibiting high spin polarization. In alternative embodiments, exemplary metals for the formation of the magnetic pinned material include iron, nickel, cobalt, chromium, boron, or manganese. Exemplary metal alloys can include the metals exemplified by the above. In another embodiment, the magnetic pinned material can be a multilayer arrangement having (1) a high spin polarization region formed from of a metal and/or metal alloy using the metals mentioned above, and (2) a region constructed of a material or materials that exhibit strong perpendicular magnetic anisotropy (strong PMA). Exemplary materials with strong PMA that can be used include a metal such as cobalt, nickel, platinum, palladium, iridium, or ruthenium, and can be arranged as alternating layers. The strong PMA region can also include alloys that exhibit strong PMA, with exemplary alloys including cobalt-iron-terbium, cobalt-iron-gadolinium, cobalt-chromium-platinum, cobalt-platinum, cobalt-palladium, iron-platinum, and/or iron-palladium. The alloys can be arranged as alternating layers. In one embodiment, combinations of these materials and regions can also be employed as the magnetic pinned material.

The blanket tunnel barrier layer 24L is composed of an insulator material and is formed at such a thickness as to provide an appropriate tunneling resistance. Exemplary materials for the blanket tunnel barrier layer 24L include magnesium oxide, aluminum oxide, and titanium oxide, or materials of higher electrical tunnel conductance, such as semiconductors or low-bandgap insulators.

The magnetic free material can be composed of a magnetic material (or a stack of magnetic materials) with a magnetization that can be changed in orientation relative to the magnetization orientation of the magnetic pinned layer. It is noted that the term “magnetic free material” denotes that the magnetic material does not have a fixed magnetization as is the case with magnetic pinned materials, but instead it is free to rotate upon application of an applied voltage. Exemplary magnetic materials for the magnetic free material include alloys and/or multilayers of cobalt, iron, alloys of cobalt-iron, nickel, alloys of nickel-iron, and alloys of cobalt-iron-boron.

If present, the non-magnetic metallic spacer material is composed of a non-magnetic metal or metal alloy that allows magnetic information to be transferred therethrough and also permits the two magnetic free layers to couple together magnetically, so that in equilibrium the first and second magnetic free layers are always parallel. The non-magnetic metallic spacer material allows for spin torque switching between a first magnetic free material and a second magnetic free material. The first magnetic free material and the second magnetic free material can include one of the magnetic free materials mentioned. The first magnetic free material can be compositionally the same as, or compositionally different from, the second magnetic free material.

The optional blanket layer of metal seed material can be composed of Pt, Pd, Ni, Rh, Ir, Re or alloys and multilayers thereof. In one example, the optional blanket layer of metal seed material is composed of Pt. If present, the blanket layer of MTJ cap material can be composed of Nb, NbN, W, WN, Ta, TaN, Ti, TiN, Ru, Mo, Cr, V, Pd, Pt, Rh, Sc, Al or other high melting point metals or conductive metal nitrides.

The MTJ-containing stack can be formed by utilizing one or more deposition processes such as, for example, sputtering, plasma enhanced atomic layer deposition (PEALD), PECVD or PVD.

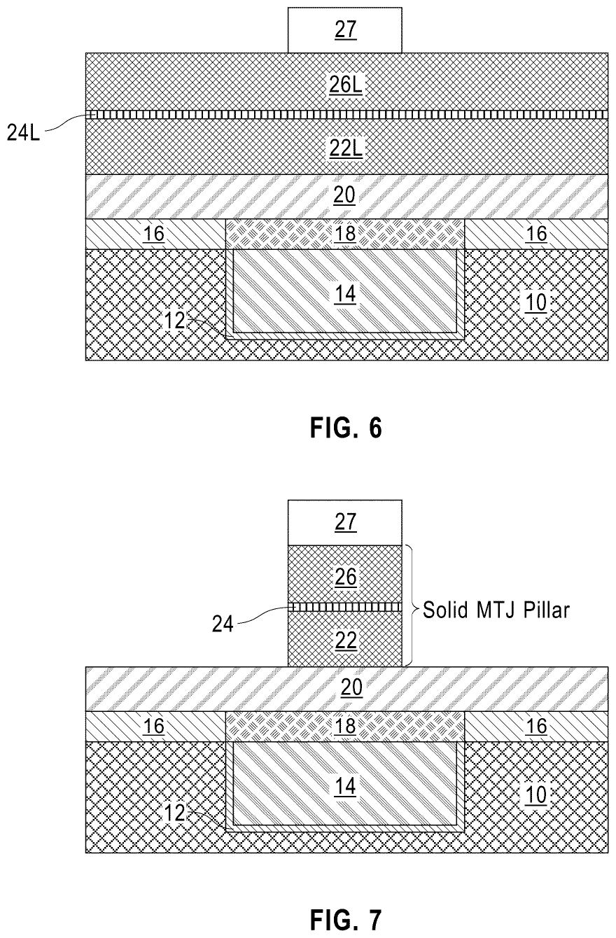

Referring now to FIG. 6, there is illustrated the exemplary structure of FIG. 5 after forming a patterned dielectric hard mask 27 on the MTJ-containing stack. The patterned dielectric hard mask 27 is composed of a dielectric hard mask material such as, for example, silicon dioxide, silicon nitride and/or silicon oxynitride. The patterned dielectric hard mask 27 can be formed by deposition of a blanket layer of dielectric hard mask material on the MTJ-containing stack, followed by lithographic patterning as defined above. The deposition of the blanket layer of dielectric hard mask material can include, but is not limited to, CVD, PECVD or PVD.

Referring now to FIG. 7, there is illustrated the exemplary structure of FIG. 6 after patterning the MTJ-containing stack including the blanket bottom magnetic material containing layer 22L, the blanket tunnel barrier layer 24L and the blank upper magnetic material containing layer 26L to provide a solid MTJ-containing pillar including a bottom magnetic material containing layer 22, a tunnel barrier layer 24 and an upper magnetic material containing layer 26. In the drawings, the term “Solid MTJ pillar” is used to denote the solid MTJ-containing pillar. The solid MTJ-containing pillar is substantially circular and it is a continuous workpiece without any openings/breaks formed therein. The patterning of the MTJ-containing stack includes an etching process such as, for example, IBE, RIE or plasma etching in which the patterned dielectric hard mask 27 is used as an etch mask. Since the MTJ-containing stack is formed on the second ILD layer 20 instead of a bottom electrode as is the case in most prior art processes, there is no metal re-sputtering risk from the bottom electrode during the MTJ-containing stack patterning process. Thus, the sidewall of the solid MTJ-containing pillar that is formed is devoid of re-sputtered bottom electrode metal particles. Also, there is a low circular edge roughness in the solid MTJ-containing pillar due to utilizing the patterned dielectric hard mask 27 as compared to prior art MTJ-containing pillars in which a metal hard mask is used during the patterning of a MTJ-containing stack.

In the present application, the bottom magnetic material containing layer 22 is a non-etched portion of the blanket bottom magnetic material containing layer 22L that is located beneath the patterned dielectric hard mask 27, the tunnel barrier layer 24 is a non-etched portion of the blanket tunnel barrier layer 24L that is located beneath the patterned dielectric hard mask 27, and the upper magnetic material containing layer 26 is a non-etched portion of the blank upper magnetic material containing layer 26L that is located beneath the patterned dielectric hard mask 27.

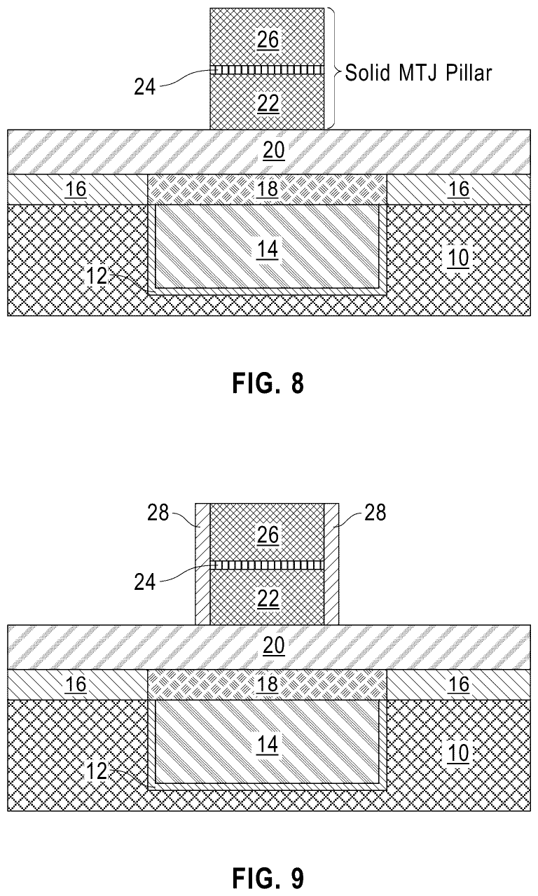

Referring now to FIG. 8, there is illustrated the exemplary structure of FIG. 7 after removing the patterned dielectric hard mask 27 from on top of the solid MTJ-containing pillar. The removal of the patterned dielectric hard mask 27 includes a material removal process that is selective in removing the dielectric hard mask 27 from the exemplary structure. The removal of the patterned dielectric hard mask 27 reveals the solid MTJ-containing pillar that was previously formed.

Referring now to FIG. 9, there is illustrated the exemplary structure of FIG. 8 after forming an encapsulation liner 28 on a sidewall of the solid MTJ-containing pillar. The encapsulation liner 28 is composed of an encapsulation dielectric material that can provide passivation to the MTJ-containing pillar. In some embodiments, the encapsulation dielectric material that provides the encapsulation liner 28 can be composed of silicon nitride. In other embodiments, the encapsulation dielectric material that provides the encapsulation liner contains atoms of silicon, carbon and hydrogen. In some embodiments, and in addition to atoms of carbon and hydrogen, the encapsulation dielectric material that provides the encapsulation liner 28 can include atoms of at least one of nitrogen and oxygen. In other embodiments, and in addition to atoms of silicon, nitrogen, carbon and hydrogen, the encapsulation dielectric material that provides the encapsulation liner 28 can include atoms of boron. In one example, the encapsulation dielectric material that provides the encapsulation liner 28 can be composed of an SiNC dielectric material that can contain atoms of silicon, carbon, hydrogen, nitrogen and oxygen. In alternative example, the encapsulation dielectric material that provides the encapsulation liner 28 can be composed of a SiBCN dielectric material that contains atoms of silicon, boron, carbon, hydrogen, and nitrogen.

The encapsulation liner 28 can be formed by depositing a conformal layer of an encapsulation dielectric material on physically exposed surfaces (i.e., sidewalls and topmost surface) of the solid MTJ-containing pillar and on a physically exposed surface of the second ILD layer 20. As used herein, the term “conformal layer” denotes that a material layer has a vertical thickness along horizontal surfaces that is substantially the same (i.e., within +5%) as the lateral thickness along vertical surfaces. The conformal layer of encapsulation dielectric material can be formed by a conformal deposition process, including but not limited to, ALD, CVD, PECVD or PVD. The formation of the encapsulation liner 28 continues by removing the conformal layer of encapsulation dielectric material from all horizonal surfaces of the exemplary structure, while maintaining the conformal layer of encapsulation dielectric material along the sidewall of the solid MTJ-containing pillar. The remaining conformal layer of encapsulation dielectric material that is present along the sidewall of the solid MTJ-containing pillar can be referred to herein as encapsulation liner 28. The encapsulation liner 28 is pillar shaped and laterally surrounds the solid MTJ-containing pillar. The removal of the conformal layer of encapsulation dielectric material from all horizonal surfaces can include a dielectric etch back process. As is illustrated in FIG. 9, the encapsulation liner 28 is located on a sidewall of each of the bottom magnetic material containing layer 22, the tunnel barrier layer 24 and the upper magnetic material containing layer 26. The encapsulation liner 28 has a bottommost surface that is in direct physical contact with a topmost surface of the second ILD layer 20, and a topmost surface that is substantially coplanar with a topmost surface of the solid MTJ-containing pillar.

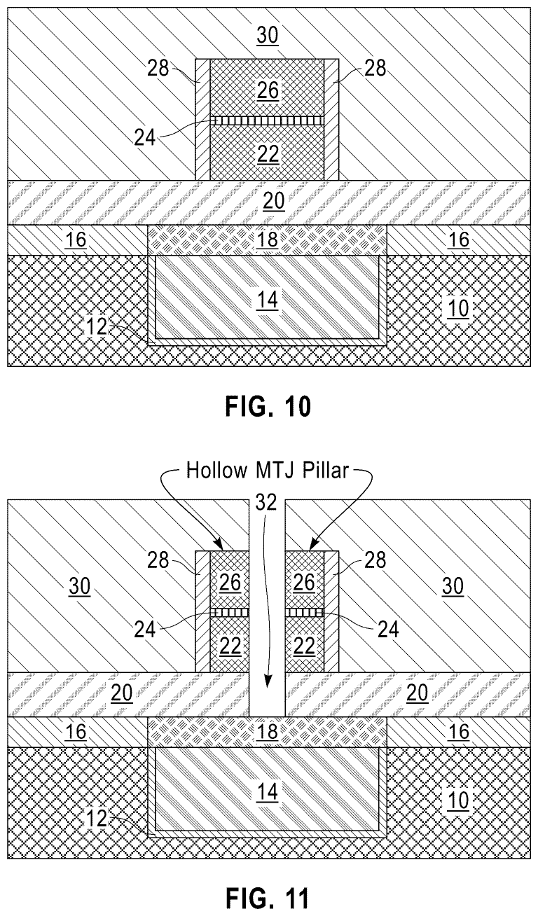

Referring now to FIG. 10, there is illustrated the exemplary structure of FIG. 9 after forming a third ILD layer 30 adjacent to the encapsulation liner 28 and on the second ILD layer 20. The third ILD layer 30 can include a dielectric material as mentioned above for the first ILD layer 10. The dielectric material that provides the third ILD layer 30 can be compositionally the same as, or compositionally different from, the dielectric material that provides the first ILD layer 10 and/or the second ILD layer 20. The dielectric material that provides the third ILD layer 30 is however compositionally different from the dielectric material that provides the encapsulation liner 28. The third ILD layer 30 can be formed by a deposition process such as, for example, CVD, PECVD, evaporation or spin-on coating. A planarization process such as, for example, CMP, can follow the deposition of the dielectric material that provides the third ILD layer 30.

Referring now to FIG. 11, there is illustrated the exemplary structure of FIG. 10 after forming an opening 32 through the third ILD layer 30, the solid MTJ-containing pillar and the second ILD layer 20 to physically expose a portion of the metal cap 18, the opening converts the solid MTJ-containing pillar into a hollow MTJ-containing pillar (in the drawings labeled as “Hollow MTJ pillar”). The hollow MTJ-containing pillar is substantially circular and it includes an unetched portion of the bottom magnetic material containing layer 22, the tunnel barrier layer 24 and the upper magnetic material containing layer 26 that laterally surrounds opening 32. The hollow MTJ-containing pillar is of unitary construction and it includes the solid MTJ-containing pillar in which opening 32 is formed therein. The hollow MTJ-containing pillar can be referred to as a toroidal or donut shaped MTJ-containing pillar including a ring of the MTJ-containing materials having a central hole. The central hole will house the central electrode structure of the present application. See, for example FIG. 24. At this point of the present application, the hollow MTJ-containing pillar has a first sidewall that is in direct physical contact with the encapsulation liner 28 and a second sidewall, opposite the first sidewall, which is physically exposed. Opening 32 can also be referred to a via opening. In the present application, the first sidewall of the hollow MTJ-containing pillar can be referred to as an outermost sidewall, while the second sidewall can be referred to as an innermost sidewall of the hollow MTJ-containing pillar. Regarding the hollow MTJ-containing structure, the outermost sidewall has a greater circumference than the innermost sidewall. Opening 32 can be formed by lithographic patterning in which the pattern transfer etch can include a single etching process or multiple etching processes. In one embodiment, the pattern transfer etch includes RIE. The pattern transfer etch stops on a surface of the metal cap 18. It is noted that after formation of opening 32, the outermost sidewall (i.e., the first sidewall) of the hollow MTJ-containing pillar is laterally surrounded by encapsulation liner 28.

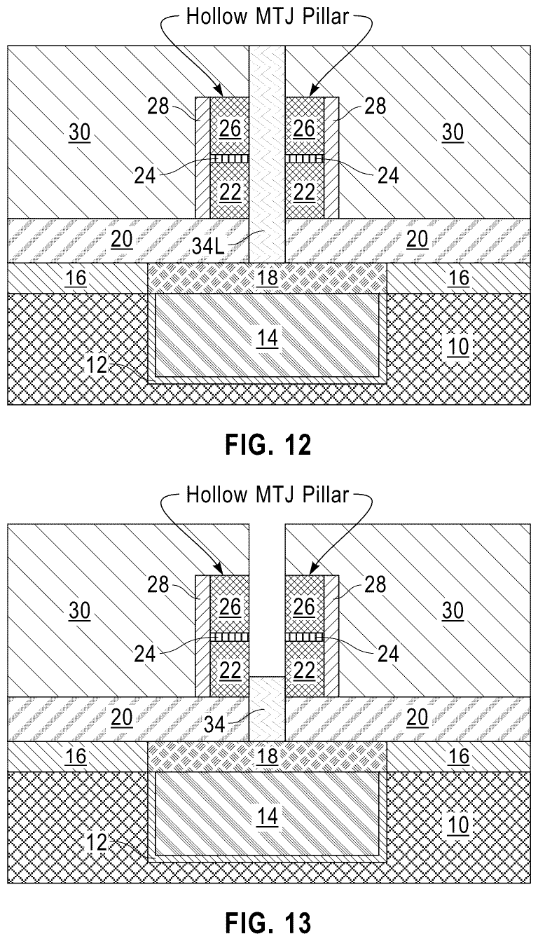

Referring now to FIG. 12, there is illustrated the exemplary structure of FIG. 11 after filling the opening 32 with a bottom electrode material containing layer 34L. The bottom electrode material containing layer 34L is composed of a conductive metal-containing material such as, for example, Ta, TaN, Ti, TiN, Ru, RuN, RuTa, RuTaN, W, WN or any combination thereof. The filling of the opening 32 with the bottom electrode material containing layer 34L includes deposition of a conductive metal-containing material, followed by a planarization process. The deposition of the conductive metal-containing material can include, but is not limited to, CVD, PECVD, ALD, sputtering or plating. At this point of the present application, the opening 32 is substantially filled with the bottom electrode material containing layer 34L. After planarization, the bottom electrode material containing layer 34L has a bottommost surface that is in direct physical contact with the physically exposed portion of the metal cap 18 and a topmost surface that is substantially coplanar with a topmost surface of the third ILD layer 30.

Referring now to FIG. 13, there is illustrated the exemplary structure of FIG. 12 after recessing the bottom electrode material containing layer 34L to a height that is located between a topmost surface and a bottom surface of the bottom magnetic material containing layer 22 of the hollow MTJ-containing pillar. The recessing of the bottom electrode material containing layer 34L includes an etching process such as, for example, RIE, that is selective in removing the bottom electrode material containing layer 34L. The recessing of the bottom electrode material containing layer 34L forms bottom electrode 34 in a bottom portion of the opening 32. In this embodiment, the bottom electrode 34 has a bottommost surface that is in direct physical contact with the metal cap 18 and a topmost surface that is located between the topmost surface and the bottom surface of the bottom magnetic material containing layer 22 of the hollow MTJ-containing pillar. In this embodiment, the bottom electrode 34 has a sidewall that is in direct physical contact with the second sidewall of the hollow MTJ-containing pillar.

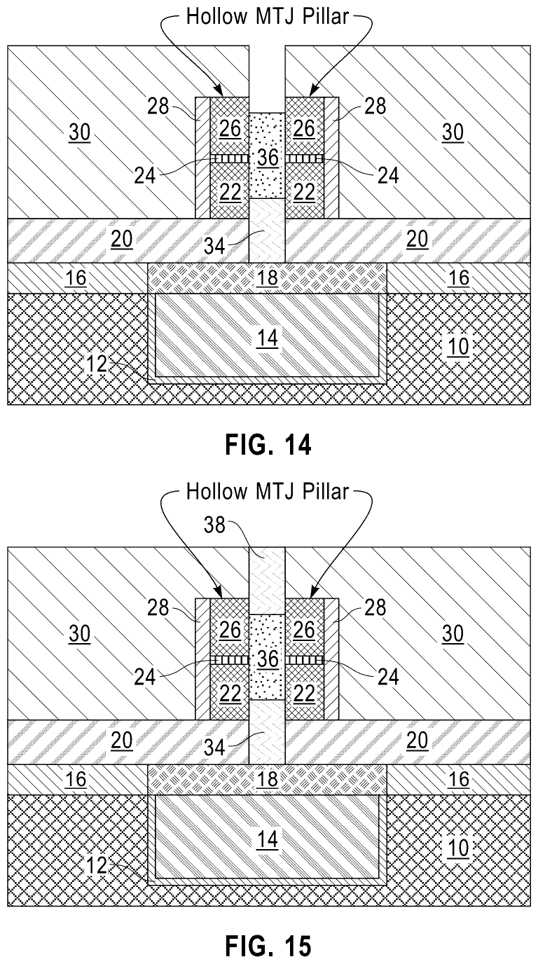

Referring now to FIG. 14, there is illustrated the exemplary structure of FIG. 13 after forming an electrode separating dielectric material layer 36 on the recessed bottom electrode layer (i.e., bottom electrode 34). The electrode separating dielectric material layer 36 is composed of a dielectric material that is compositionally different from the tunnel barrier layer 24 and the dielectric material that provides the third ILD layer 30. Illustrative examples of dielectric materials that can be used as the electrode separating dielectric material layer 36 include, but are not limited to, SiN, SiC, SiCOH or SiCN. The electrode separating dielectric material layer 36 can be formed by deposition of the dielectric material, followed by planarization and a recess etch. The deposition used in forming the electrode separating dielectric material layer 36 can include, for example, CVD, PECVD or evaporation. The electrode separating dielectric material layer 36 has a bottommost surface that is in direct physical contact with the bottom electrode 34 and a topmost surface that is located between a bottommost surface and a topmost surface of the upper magnetic material containing layer 26 of the hollow MTJ-containing pillar. The electrode separating dielectric material layer 36 has a sidewall that is in direct physical contact with the second sidewall of the hollow MTJ-containing pillar.

Referring now to FIG. 15, there is illustrated the exemplary structure of FIG. 14 after forming a top electrode 38 on the electrode separating dielectric material layer 36. The top electrode 38 is composed of a conductive metal-containing material as mentioned above for the bottom electrode material containing layer 34L. The conductive metal-containing material that provides the top electrode 38 can be compositionally the same as, or compositionally different from, the conductive metal-containing material that bottom electrode material containing layer 34L (and the bottom electrode 34). The top electrode 38 can be formed by deposition of a conductive metal-containing material, and planarization. The deposition of the conductive metal-containing material can include, but is not limited to, CVD, PECVD, ALD, sputtering or plating. In this embodiments, the top electrode 38 has a bottommost surface that is in direct physical contact with the electrode separating dielectric material layer 36 and a topmost surface that is substantially coplanar with a topmost surface of the third ILD layer 30. The top electrode 38 has a sidewall that is in direct physical contact with the second sidewall of the hollow MTJ-containing pillar. Collectively, the bottom electrode 34, the electrode separating dielectric material layer 36, and the top electrode 38 are components of a central electrode structure. The central electrode structure extends entirely through, and is laterally surrounded by, the hollow MTJ-containing pillar; see for, example, FIG. 24. As is shown in FIG. 15, the central electrode structure extends above and below the hollow MTJ-containing pillar. Notably, the top electrode 38 extends above the hollow MTJ-containing pillar and the bottom electrode 34 extends below the hollow MTJ-containing pillar. In the present application, hollow MTJ-containing pillar is contacted by the bottom electrode 34 from below, and by the top electrode 38 from above. In this embodiment, the top electrode 38 has a sidewall that is vertically aligned to a sidewall of the bottom electrode 34, as well as with a sidewall of the electrode separating dielectric material layer 36.

The presence of the central electrode structure in the exemplary structure can extend the scalability of a memory device that includes the same due to an enlarged process window for MTJ-containing stack patterning. Also, the presence of the central electrode structure in the exemplary structure can improve the performance of a memory device that includes the same due to a reduction of tunnel barrier shorts.

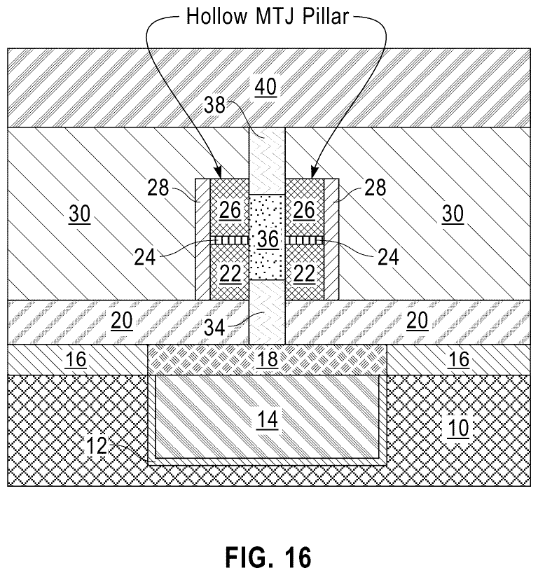

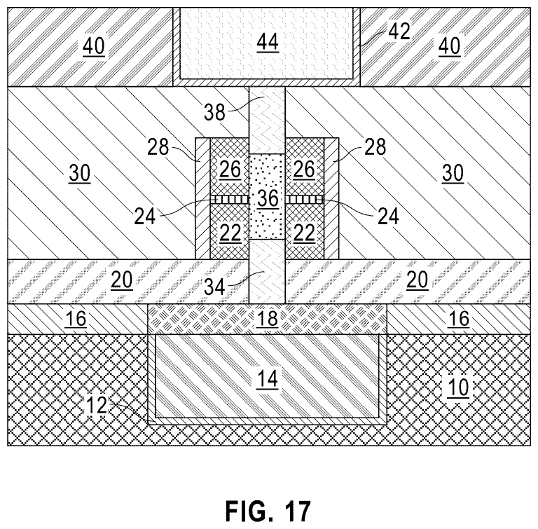

Referring now to FIG. 16, there is illustrated the exemplary structure of FIG. 15 after forming a fourth ILD layer 40. The fourth ILD layer 40 is formed on top of the third ILD layer 30 and on top of the top electrode 38 of the central electrode structure of the present application. The fourth ILD layer 40 can include a dielectric material as mentioned above for the first ILD layer 10. The dielectric material that provides the fourth ILD layer 40 can be compositionally the same as, or compositionally different from, the dielectric material that provides the first ILD layer 10 and/or the second ILD layer 20 and/or the third ILD layer 30. The fourth ILD layer 40 can be formed by a deposition process such as, for example, CVD, PECVD, evaporation or spin-on coating. A planarization process such as, for example, CMP, can follow the deposition of the dielectric material that provides the fourth ILD layer 40.

Referring now to FIG. 17, there is illustrated the exemplary structure of FIG. 16 after forming a second electrically conductive structure 44 embedded in the fourth ILD layer 40 and in electrical contact with the top electrode 38. An optional second diffusion barrier liner 42 can be present along a sidewall and a bottom surface of the second electrically conductive structure 44. The second electrically conductive structure 44 is composed of electrically conductive material as mentioned above for the first electrically conductive structure 14. The optional second diffusion barrier liner 42 is composed of a diffusion barrier material as mentioned above for the optional first diffusion barrier liner 12. The optional second diffusion barrier liner 42 and the second electrically conductive structure 44 can be formed by a damascene process as mentioned above in forming the optional first diffusion barrier liner 12 and the first electrically conductive structure 14.

As illustrated in FIG. 17, a memory device is provided in which the second electrically conductive structure 44 is in electrical contact with the top electrode 38 of the central electrode structure of the present application, and the first electrically conductive structure 14 is in electrical contact with the bottom electrode 34 of the central electrode structure via the metal cap 18. The central electrode structure which extends entirely through, and is laterally surrounded by, the hollow MTJ-containing pillar is in electrical contact with the hollow MTJ-containing pillar. In the embodiment, bottom electrode 34 is in direct physical contact with a sidewall of the bottom magnetic material containing layer 22 of the hollow MTJ-containing pillar, and the top electrode 38 is in direct physical contact with a sidewall of the upper magnetic containing layer 26 of the hollow MTJ-containing pillar. In this illustrated embodiment, no electrode liners are present in the central electrode structure.

FIG. 17 illustrates a memory device in accordance with an embodiment of the present application. Notably, the memory device illustrated in FIG. 17 includes first electrically conductive structure 14, metal cap 18 located on the first electrically conductive structure 14, and a central electrode structure that extends entirely through, and is laterally surrounding by hollow MTJ-containing pillar. In this embodiment, the central electrode structure includes top electrode 38 spaced apart from bottom electrode 34 in which the bottom electrode 34 is in direct physical contact with the metal cap 18. The memory device further includes second electrically conductive structure 44 located above, and in electrical contact with, the top electrode 38.

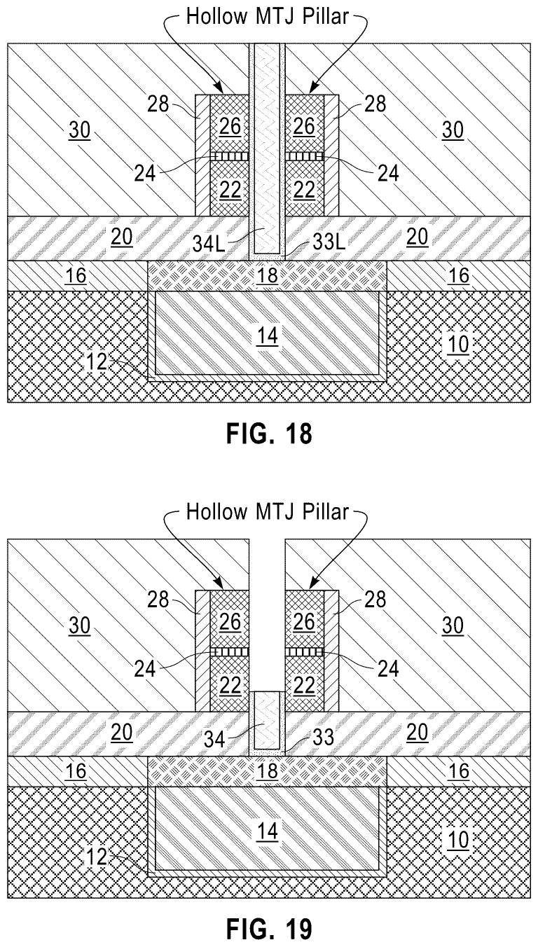

In the illustrated embodiment depicted in FIGS. 18-24, electrode liners are present in the central electrode structure. Notably, a bottom electrode liner 33 and a top electrode liner 37 are both present in the central electrode structure illustrated in FIGS. 18-24. Although the central electrode structure is depicted to include both bottom electrode liner 33 and top electrode liner 37, the present application contemplates embodiments in which only one of those two electrode liners are present in the central electrode system. Notably, the present application includes an embodiment in which only the bottom electrode liner 33 or only the top electrode liner 37 is present in the central electrode system.

Referring now to FIG. 18, there is illustrated the exemplary structure of FIG. 11 after filling the opening 32 with a metal liner 33L and a bottom electrode material containing layer 34L. The metal liner 33L is composed of a diffusion barrier material as mentioned above for the first diffusion barrier liner 12. The bottom electrode material containing layer 34L is composed of a conductive metal-containing material as mentioned above for the previous embodiment of the present application. The metal liner 33L and the bottom electrode material containing layer 34L can be formed by first depositing a layer of the diffusion barrier material that provides the metal liner 33L in the opening 32 and on top of the third ILD layer 30. The layer of the diffusion barrier material lines the sidewalls and the bottom portion of the opening 32. Next, the conductive metal-containing material is second deposited in the opening 32 and on top of the layer of the diffusion barrier material. A planarization process is then performed that removes the conductive metal-containing material layer of the diffusion barrier material that is located outside of the opening 32 and on top of the third ILD layer 30. The remaining layer of the diffusion barrier material in the opening 32 is the metal liner 33L, while the remaining conductive metal-containing material in the opening is the bottom electrode material containing layer 34L. As is shown, the metal liner 33L is located along a sidewall and a bottom surface of the bottom electrode material containing layer 34L.

Referring now to FIG. 19, there is illustrated the exemplary structure of FIG. 18 after recessing the metal liner 33L and the bottom electrode material containing layer 34L to a height that is located between a topmost surface and a bottom surface of the bottom magnetic material containing layer 22 of the hollow MTJ-containing pillar. The recessing of the metal liner 33L and the bottom electrode material containing layer 34L includes an etching process such as, for example, RIE, that is selective in removing the metal liner 33L and the bottom electrode material containing layer 34L. The recessing of the metal liner 33L and the bottom electrode material containing layer 34L forms bottom electrode liner 33 and bottom electrode 34, respectively, in a bottom portion of the opening 32. In this embodiment, the bottom electrode liner 33 has a bottommost surface that is in direct physical contact with the metal cap 18 and a topmost surface that is located between the topmost surface and the bottom surface of the bottom magnetic material containing layer 22 of the hollow MTJ-containing pillar. In this embodiment, the topmost surface of bottom electrode liner 33 is substantially coplanar with a topmost surface of the bottom electrode 34. In this embodiment, the bottom electrode 34 is spaced apart from the hollow MTJ-containing pillar and the metal cap 18 by the bottom metal liner 33.

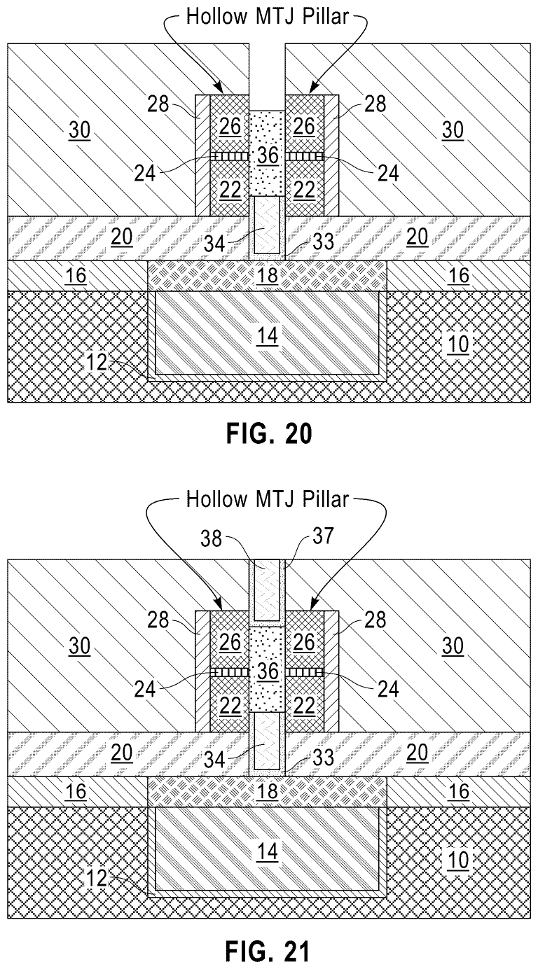

Referring now to FIG. 20, there is illustrated the exemplary structure of FIG. 19 after forming an electrode separating dielectric material layer 36 on the recessed bottom electrode layer (i.e., bottom electrode 34). In this embodiment, the electrode separating dielectric material layer 36 is also formed on a topmost surface of the bottom electrode liner 33. The electrode separating dielectric material layer 36 used in this embodiment of the present application is the same as that described above for the embodiment illustrated in FIG. 14. In this embodiment, the electrode separating dielectric material layer 36 has a bottommost surface that is in direct physical contact with the bottom electrode 34 and with the bottom electrode liner 33 and a topmost surface that is located between a bottommost surface and a topmost surface of the upper magnetic material containing layer 26 of the hollow MTJ-containing pillar. The electrode separating dielectric material layer 36 has a sidewall that is in direct physical contact with the second sidewall of the hollow MTJ-containing pillar.

Referring now to FIG. 21, there is illustrated the exemplary structure of FIG. 20 after forming a top electrode liner 37 and top electrode 38 on the electrode separating dielectric material layer 36. The top electrode liner 37 is composed of a diffusion barrier material as mentioned above for the first diffusion barrier liner 12. The top electrode 38 is composed of a conductive metal-containing material as mentioned above for the previous embodiment of the present application. The top electrode liner 37 and top electrode 38 can be formed by first depositing a layer of the diffusion barrier material and then second depositing the conductive metal-containing material on the layer of diffusion barrier material. A planarization process is then employed to remove the conductive metal-containing material and the layer of diffusion barrier material that is located outside of the opening 32 and on top of the third ILD layer 30. The remaining layer of diffusion barrier material in the opening 32 provides the top electrode liner 37 and the remaining conductive metal-containing material in the opening 32 provides the top electrode 38.

The top electrode liner 37 has a sidewall that is in direct physical contact with the second sidewall of the hollow MTJ-containing pillar. The top electrode liner 37 is located on a sidewall of the top electrode 38 and on a bottom surface of the top electrode 38. Collectively, the bottom electrode liner 33, the bottom electrode 34, the electrode separating dielectric material layer 36, the top electrode liner 37 and the top electrode 38 are components of a central electrode structure. The central electrode structure extends entirely through, and is laterally surrounded by, the hollow MTJ-containing pillar, see, for example, FIG. 24. The central electrode structure is in direct physical contact with the second sidewall of the hollow MTJ-containing pillar; note that the first sidewall of the hollow MTJ-containing pillar is in direct physical contact with the encapsulation liner 28. In this embodiment, the top electrode liner 37 has a topmost surface that is substantially coplanar with a topmost surface of the top electrode 38 and the topmost surface of each of the top electrode liner 37 and the top electrode 38 are substantially coplanar with a topmost surface of the third ILD layer 30. In this embodiment, the bottom electrode liner 33 and the top electrode liner 37 prevent unwanted metal diffusion to occur into, or out from, the hollow MTJ-containing pillar.

The presence of the central electrode structure in the exemplary structure can extend the scalability of a memory device that includes the same due to an enlarged process window for MTJ-containing stack patterning. Also, the presence of the central electrode structure in the exemplary structure can improve the performance of a memory device that includes the same due to a reduction of tunnel barrier shorts.

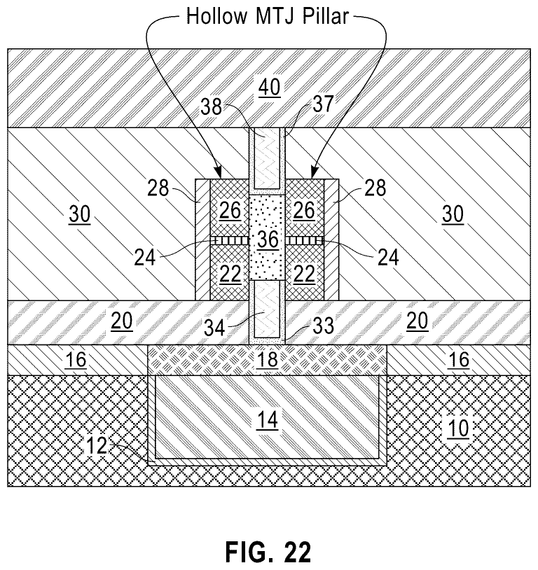

Referring now to FIG. 22, there is illustrated the exemplary structure of FIG. 21 after forming a fourth ILD layer 40. The fourth ILD layer 40 is formed on top of the third ILD layer 30 and on top of the top electrode liner 37 and the top electrode 38 of the central electrode structure of the present application. The fourth ILD layer 40 can include a dielectric material as mentioned above for the first ILD layer 10. The dielectric material that provides the fourth ILD layer 40 can be compositionally the same as, or compositionally different from, the dielectric material that provides the first ILD layer 10 and/or the second ILD layer 20 and/or the third ILD layer 30. The fourth ILD layer 40 can be formed by a deposition process such as, for example, CVD, PECVD, evaporation or spin-on coating. A planarization process such as, for example, CMP, can follow the deposition of the dielectric material that provides the fourth ILD layer 40.

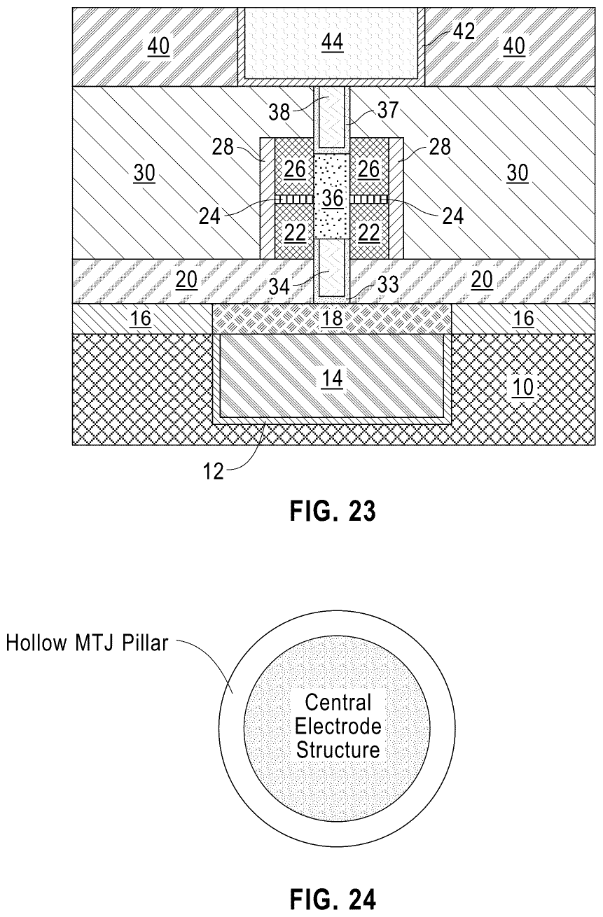

Referring now to FIG. 23, there is illustrated the exemplary structure of FIG. 22 after forming second electrically conductive structure 44 embedded in the fourth ILD layer 40 and in electrical contact with the top electrode 38. An optional second diffusion barrier liner 42 can be present along a sidewall and a bottom surface of the second electrically conductive structure 44. The second electrically conductive structure 44 is composed of electrically conductive material as mentioned above for the first electrically conductive structure 14. The optional second diffusion barrier liner 42 is composed of a diffusion barrier material as mentioned above for the optional first diffusion barrier liner 12. The optional second diffusion barrier liner 42 and the second electrically conductive structure 44 can be formed by a damascene process as mentioned above in forming the optional first diffusion barrier liner 12 and the first electrically conductive structure 14.

As illustrated in FIG. 23, a memory device is provided in which the second electrically conductive structure 44 is in electrical contact with the top electrode 38 of the central electrode structure of the present application, and the first electrically conductive structure 14 is in electrical contact with the bottom electrode 34 of the central electrode structure via the metal cap 18, The central electrode structure which extends entirely through, and is laterally surrounded by, the hollow MTJ-containing pillar is in electrical contact with the hollow MTJ-containing pillar. In this illustrated embodiment, bottom electrode liner 33 and top electrode liner 37 are present in the central electrode structure and the liners aid in preventing unwanted metal diffusion to occur into, or out from, the hollow MTJ-containing pillar.

FIG. 23 illustrates a memory device in accordance with an embodiment of the present application. Notably, the memory device illustrated in FIG. 23 includes first electrically conductive structure 14, metal cap 18 located on the first electrically conductive structure 14, and a central electrode structure extending entirely through, and laterally surrounded by, the hollow MTJ-containing pillar. In this embodiment, the central electrode structure includes top electrode 38 spaced apart from bottom electrode 34, bottom electrode liner 33 located on a sidewall and a bottom surface of the bottom electrode 34, and top electrode liner 37 located on a sidewall and a bottom surface of the top electrode 38. In this embodiment, the bottom electrode liner 33 lands on the metal cap 18. The memory device illustrated in FIG. 23 further includes second electrically conductive structure 44 located above, and in electrical contact with, the top electrode 38.

In a further embodiment of the present application, which can be readily derived from FIG. 23 the memory device first electrically conductive structure 14, metal cap 18 located on the first electrically conductive structure 14, and a central electrode structure extending entirely through, and laterally surrounded by, the hollow MTJ-containing pillar. In this further embodiment, central electrode structure includes top electrode 38 spaced apart from bottom electrode 34 and an electrode liner (i.e., either bottom electrode liner 33 of top electrode liner 37) located on a sidewall and a bottom surface of either the top electrode 38 or the bottom electrode 34. In this embodiment the bottom electrode 34 is in electrical contact (either directly or indirectly) with the metal cap 18.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A memory device comprising:
a first electrically conductive structure;
a metal cap located on the first electrically conductive structure;
a central electrode structure extending entirely through, and laterally surrounded by, a hollow magnetic tunnel junction (MTJ)-containing pillar, wherein the central electrode structure comprises a top electrode spaced apart from a bottom electrode, wherein the bottom electrode is in direct physical contact with the metal cap; and
a second electrically conductive structure located above, and in electrical contact with, the top electrode.

2. The memory device of claim 1, wherein the central electrode structure further comprises an electrode separating dielectric material layer located between the top electrode and the bottom electrode.

3. The memory device of claim 1, wherein the hollow MTJ-containing pillar comprises a bottom magnetic material containing layer, a tunnel barrier layer and an upper magnetic material containing layer, wherein the bottom magnetic material containing layer comprises a magnetic free material, and the upper magnetic material containing layer comprises a magnetic reference material.

4. The memory device of claim 1, wherein the hollow MTJ-containing pillar comprises a bottom magnetic material containing layer, a tunnel barrier layer and an upper magnetic material containing layer, wherein the bottom magnetic material containing layer comprises a magnetic reference material, and the upper magnetic material containing layer comprises a magnetic free material.

5. The memory device of claim 1, wherein the hollow MTJ-containing pillar is laterally surrounded by an encapsulation liner.

6. The memory device of claim 1, wherein the bottom electrode is in direct physical contact with a sidewall of a bottom magnetic material containing layer of the hollow MTJ-containing pillar, and the top electrode is in direct physical contact with a sidewall of an upper magnetic material containing layer of the hollow MTJ-containing pillar.

7. The memory device of claim 1, wherein the top electrode of the central electrode structure extends above hollow MTJ-containing pillar, and the bottom electrode of the central electrode structure extends below the hollow MTJ-containing pillar.

8. The memory device of claim 1, wherein the top electrode has a sidewall that is vertically aligned with a sidewall of the bottom electrode.

9. The memory device of claim 1, wherein the hollow MTJ-containing pillar is toroidal shaped.

10. A memory device comprising:
a first electrically conductive structure;
a metal cap located on the first electrically conductive structure;
a central electrode structure extending entirely through, and laterally surrounded by, a hollow magnetic tunnel junction (MTJ)-containing pillar, wherein the central electrode structure comprises a top electrode spaced apart from a bottom electrode, a bottom electrode liner located on a sidewall and a bottom surface of the bottom electrode, and a top electrode liner located on a sidewall and a bottom surface of the top electrode, wherein the bottom electrode liner lands on the metal cap; and
a second electrically conductive structure located above, and in electrical contact with, the top electrode.

11. The memory device of claim 10, wherein the central electrode structure further comprises an electrode separating dielectric material layer located between the top electrode and the bottom electrode.

12. The memory device of claim 10, wherein hollow MTJ-containing pillar comprises a bottom magnetic material containing layer, a tunnel barrier layer and an upper magnetic material containing layer, wherein the bottom magnetic material containing layer comprises a magnetic free material, and the upper magnetic material containing layer comprises a magnetic reference material.

13. The memory device of claim 10, wherein hollow MTJ-containing pillar comprises a bottom magnetic material containing layer, a tunnel barrier layer and an upper magnetic material containing layer, wherein the bottom magnetic material containing layer comprises a magnetic reference material, and the upper magnetic material containing layer comprises a magnetic free material.

14. The memory device of claim 10, wherein the hollow MTJ-containing pillar is laterally surrounded by an encapsulation liner.

15. The memory device of claim 10, wherein the bottom electrode is spaced apart from a sidewall of a bottom magnetic material containing layer of the hollow MTJ-containing pillar by the bottom electrode liner, and the top electrode is spaced apart from a sidewall of an upper magnetic material containing layer by the top electrode liner.

16. The memory device of claim 10, wherein the top electrode of the central electrode structure extends above the hollow MTJ-containing pillar, and the bottom electrode of the central electrode structure extends below the hollow MTJ-containing pillar.

17. A memory device comprising:
a first electrically conductive structure;
a metal cap located on the first electrically conductive structure;
a central electrode structure extending entirely through, and laterally surrounded by, a hollow magnetic tunnel junction (MTJ)-containing pillar, wherein the central electrode structure comprises a top electrode spaced apart from a bottom electrode and an electrode liner located on a sidewall and a bottom surface of either the top electrode or the bottom electrode, wherein the bottom electrode is in electrical contact with the metal cap; and
a second electrically conductive structure located above, and in electrical contact with, the top electrode.

18. The memory device of claim 17, wherein the hollow MTJ-containing pillar comprises a bottom magnetic material containing layer, a tunnel barrier layer and an upper magnetic material containing layer, wherein the bottom magnetic material containing layer comprises a magnetic free material, and the upper magnetic material containing layer comprises a magnetic reference material.

19. The memory device of claim 17, wherein the hollow MTJ-containing pillar comprises a bottom magnetic material containing layer, a tunnel barrier layer and an upper magnetic material containing layer, wherein the bottom magnetic material containing layer comprises a magnetic reference material, and the upper magnetic material containing layer comprises a magnetic free material.

20. The memory device of claim 17, wherein the hollow MTJ-containing pillar is laterally surrounded by an encapsulation liner.
